(19) United States
(12) Patent Application Publication
(10) Pub. No.: US 2018/0362179 A1
(43) Pub. Date: Dec. 20, 2018

(54) COOLING AN UNMANNED AERIAL VEHICLE

(71) Applicant: T-Mobile, U.S.A., Inc., Bellevue, WA (US)

(72) Inventors: Joshua Finger, Covington, WA (US); Sean Murphy, Renton, WA (US)

(21) Appl. No.: 15/628,571

(22) Filed: Jun. 20, 2017

(51) Int. Cl. B64D 33/08; F01P 5/06; H05K 7/20; B64C 27/20; B64C 39/02

(52) U.S. Cl. CPC B64D 33/08; F01P 5/06; H05K 7/20409; B64C 27/20; B64C 39/024; F01P 2050/20; B64C 2201/042; B64C 2201/088; B64C 2201/108; B64C 2201/162; B64C 2201/027

(57) ABSTRACT

Techniques are disclosed for cooling an unmanned aerial vehicle (UAV). In some examples, a heat sink is coupled to a portion of the UAV that is to be cooled. One or more heat pipes are coupled to the shim, and extend to one or more propulsion engines of the UAV. Liquid in a heat pipe is heated to gaseous form at the heat sink, and the vapor travels to a portion of the heat pipe near the propulsion engine, where the vapor is cooled by air moved by the propulsion engine, upon which the vapor returns to liquid form and travels back to the heat sink.

### BACKGROUND

An unmanned aerial vehicle (UAV), which is sometimes referred to as a drone), is an aircraft that is not piloted by someone aboard the UAV. In some examples, a UAV can be controlled by a person on the ground, who uses a computing device to wirelessly communicate with the UAV. In other examples, the UAV can operate autonomously.

### BRIEF DESCRIPTION OF THE DRAWINGS

The Detailed Description is set forth with reference to the accompanying Figures.

FIG. 1 illustrates an example UAV with a cooling mechanism.

FIG. 2 illustrates an example of a heat sink that connects a portion of a UAV to be cooled with a heat pipe.

FIG. 3 illustrates an example of a heat pipe for a UAV that includes a heat pipe connected to one propulsion engine.

FIG. 4 illustrates a second example of a heat pipe for a UAV that includes a heat pipe connected to two propulsion engines.

FIG. 5 illustrates a third example of a heat pipe for a UAV that includes the heat pipe serving as a bumper guard for the UAV.

FIG. 6 illustrates an example of fins on a heat pipe for a UAV.

FIG. 7 illustrates an example of how liquid and vapor can flow through a heat pipe to cool a UAV.

FIG. 8 illustrates a flow diagram of example operating procedures for forming a UAV that includes a heat pipe.

FIG. 9 illustrates a flow diagram of example operating procedures for using a heat pipe to cool a UAV.

### DETAILED DESCRIPTION

### Overview

A wireless telecommunications network can enable a user device, such as a mobile phone, (sometimes referred to as user equipment, or UE) to send and receive data, including voice data. As part of communicating via the telecommunications network, a user device can establish and use a wireless communications channel with a radio base station of the telecommunications network. Radio base stations such as cellular network towers (sometimes referred to as a cell tower or cell site) can generally comprise antennas that are mounted to a mast or rooftop, have power outputs on the order of tens of watts, and have a range of approximately 20 miles. These types of radio base stations are sometimes referred to as macrocells.

There are also smaller radio base stations that are sometimes referred to as small cells (which encompasses types of radio base stations referred to as microcells, picocells, and femtocells). These smaller radio base stations are generally physically smaller, with smaller power output, and a smaller range.

A small cell can be attached to a UAV. A use for this can be to provide access to a telecommunications network where there has been a power outage that affects the pre-existing radio base stations, or where there has been a natural disaster that otherwise disables the pre-existing radio base stations. Another use for a UAV carrying a small cell can be a temporary event that attracts a large number of people to a relatively small area, such as a music festival, or a sporting event. In such scenarios, one or more UAVs carrying small cells can be deployed to the affected area to provide network coverage to user devices in the area. A small cell carried by a UAV can have at least a portion of the small cell's backhaul to the core network be implemented wirelessly, so that the UAV does not have a wire between the UAV and the ground.

Where a small cell is carried by a UAV, there can be considerations on how to cool the small cell. As a small cell operates, a small cell generally produces heat, which is to be dissipated at a rate sufficient that the small cell does not overheat to the point where the small cell's operation is impaired. Since a UAV generally is powered by a battery, attempts can be made to minimize power consumption while providing small cell functionality. These attempts to minimize power consumption by a UAV can extend to cooling the small cell.

One way to minimize power consumption by a UAV is to passively cool the small cell. Passive cooling can be considered to be cooling a device without directly consuming electricity to do so (though, a passive cooling apparatus can add weight to a UAV, which in turn can involve using more power to keep this heavier UAV in the air). Passive cooling can be viewed in contrast to active cooling, where power is directly consumed as part of the active cooling process.

One approach to passively cooling a small cell on a UAV is to use a heat pipe to transfer heat from the small cell, where heat is generated, to one or more of the UAV's propulsion engines, where air flow from the propulsion engine(s) can aid in dissipating this heat. There can be more air flow at a UAV's propulsion engine then elsewhere at the UAV because, even where a UAV is hovering at a fixed position, the propulsion engine(s) can be generating air flow as part of keeping the UAV aloft.

A heat pipe generally is a chamber that contains a liquid. In various examples, this liquid can be ammonia, methanol, ethanol, or water. These different liquids can have different boiling points, and the use of a particular liquid can be selected based on a temperature of an object to be cooled, where an operating temperature of the object exceeds the boiling point of the liquid. While various examples described herein can involve the use of water as the liquid in the heat pipe, it can be appreciated that there can be examples where other liquids are used in the heat pipe.

As the liquid absorbs heat at one point in the heat pipe, e.g., the heat pipe's hot interface, the liquid vaporizes. The vapor travels along the heat pipe to a second point, e.g., the heat pipe's cold interface, where the vapor dissipates heat and condenses back into a liquid. The liquid travels from the cold interface to the hot interface, where the liquid is vaporized again. A variety of passive methods can be used to cause the vapor and liquid to travel, such as capillary action, centrifugal force, and gravity. Using gravity as an example, where the hot interface is located lower than the cold interface, the vapor will travel upward from the hot interface (where the vapor is created) to the cold interface, and the liquid will travel downward from the cold interface (where the liquid is created) to the hot interface.

While the embodiments described herein generally focus on the cooling of a network cell in a UAV, it can be appreciated that these cooling techniques can be applied to cooling other computing devices.

UAV with a Cooling Mechanism

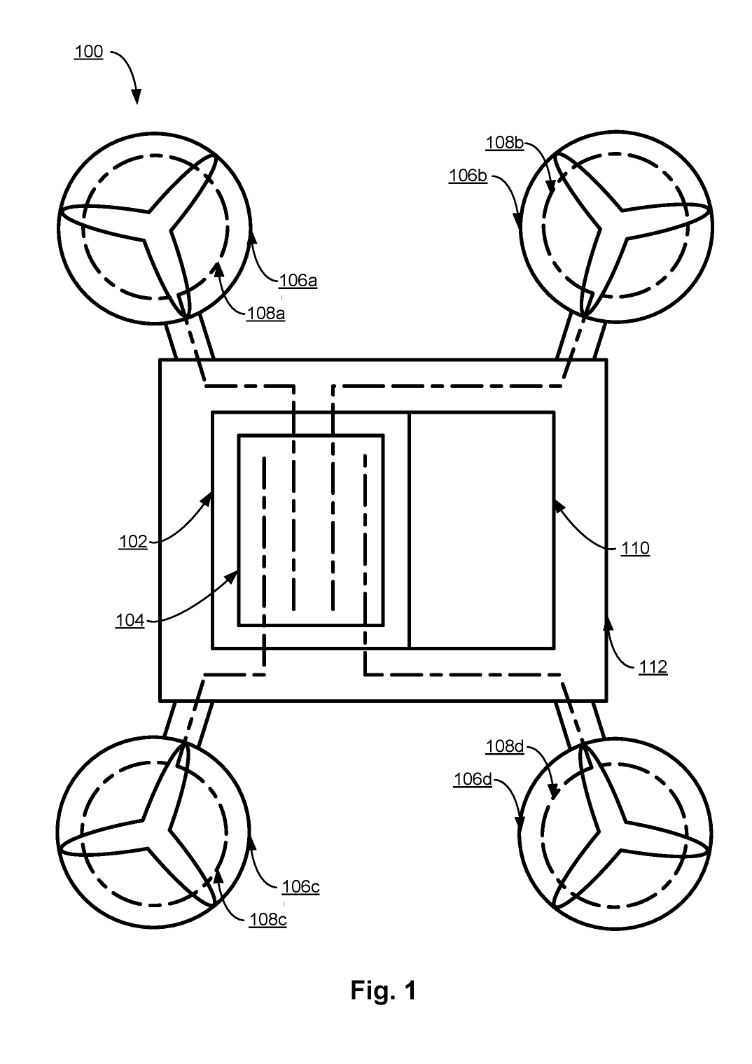

FIG. 1 illustrates an example UAV with a cooling mechanism. As depicted, UAV 100 comprises UAV body 112, which in turn comprises small cell 102 (sometimes referred to as a network cell), heat sink 104 (sometimes referred to as a heat shim), and power source 110. UAV 100 also comprises propulsion engine 106a, propulsion engine 106b, propulsion engine 106c, propulsion engine 106d, heat pipe 108a, heat pipe 108b, heat pipe 108c, heat pipe 108d. UAV 100 can also comprise various other components, such as a camera, which are not depicted in FIG. 1 so as to emphasize other components of UAV 100.

Small cell 102 is configured to provide wireless connectivity for one or more user devices to communicate with a telecommunications network, of which small cell 102 is a part. Small cell 102 can communicate with a user device according to a variety of protocols, such as a Long Term Evolution (LTE) wireless communications protocol, or a LTE in unlicensed spectrum (LTE-u) wireless communications protocol. Small cell 102 can also communicate with a core network of the telecommunications network via a backhaul, of which at least part can be a wireless communications channel.

Small cell 102 generates heat while operating, and some of this heat is absorbed by heat sink 104, which is coupled to small cell 102. Heat sink 104 is a passive heat exchanger that transfers at least some of the heat generated by small cell 102 away from small cell 102 and dissipates the heat. That is, heat sink 104 is configured to draw heat from small cell 102. Heat sink 104 can be made up of a metal that has beneficial heat transfer properties, such as copper or aluminum.

Aluminum is generally less dense than copper, and can provide equivalent heat dissipation for small cell 102 at a lower weight of heat sink 104. This lower weight of heat sink 104 can save on power consumption by UAV 100, since UAV 100 will have less weight to keep aloft.

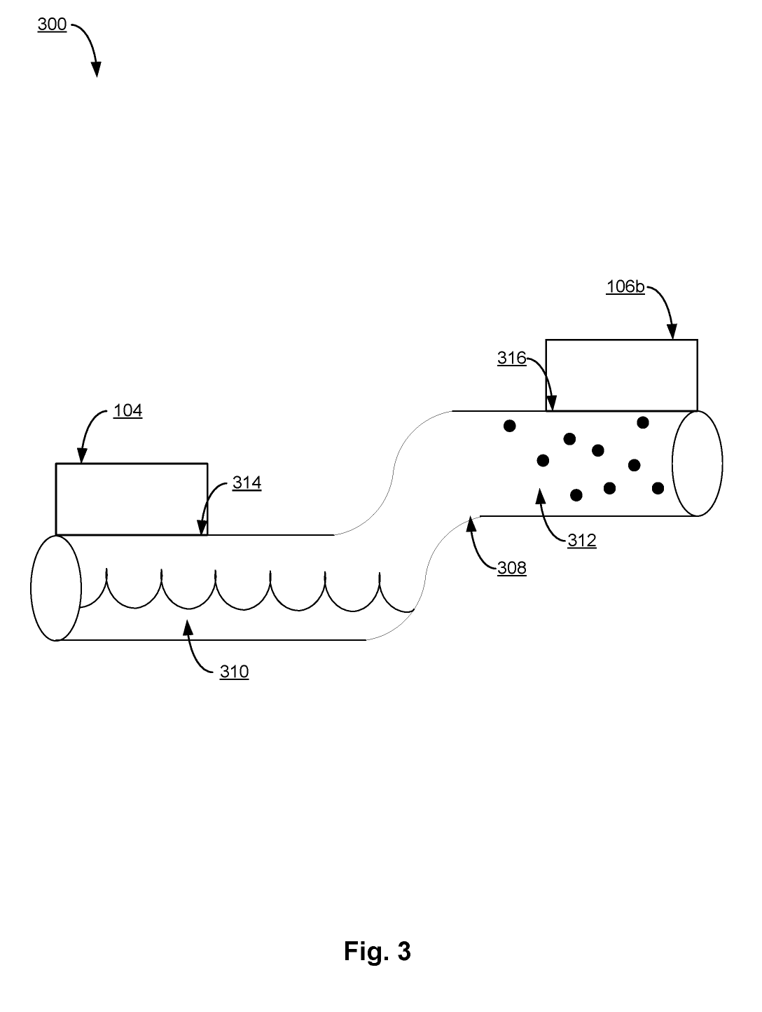

Heat pipe 108a, heat pipe 108b, heat pipe 108c, and heat pipe 108d are coupled to heat sink 104. Heat pipes 108a-d are depicted in FIG. 1 with dashed lines. It can be appreciated that heat pipes are depicted in this manner for clarity—so as to distinguish heat pipes 108a-d from other elements of UAV 100—and that heat pipes 108a-d can be continuous pipes, such as depicted in FIGS. 3, 4, 6, and 7.

As depicted, there is a hot interface for each of the four heat pipes, in which a hot interface is a point at which heat is absorbed by the heat pipe, and due to this absorbed heat, a material within the heat pipe undergoes a state change from liquid form to vapor form. That is, each of heat pipes 108a-108d are configured to draw heat from heat sink 104. As depicted, each of heat pipes 108a-108d comprise a portion that is coupled to a propulsion engine and that is configured in a substantially circular shape proximal to where a respective heat pipe is coupled to the propulsion engine.

It can be appreciated that, where a portion of a heat pipe that is coupled to a propulsion engine might not be directly coupled to a portion of the propulsion engine that creates propulsion (e.g., a propeller). That is, this portion of the heat pipe that is coupled to the propulsion engine might be coupled to a housing of the propulsion engine, or to another portion of the propulsion engine that places this portion of the heat pipe in an air flow of the propulsion engine when the propulsion engine is operating. By being placed in the air flow of the propulsion engine when the propulsion engine is operating, this air flow can act as a cold interface to the heat pipe, allowing heat to dissipate at this cold interface.

In some examples, each of these four heat pipes is a separate heat pipe, i.e., the heat pipe is sealed off from the other heat pipes, so that liquid or vapor within one heat pipe does not travel to another heat pipe. In other examples, two or more of these heat pipes are connected. For instance, heat pipe 108a and heat pipe 108b can be joined together so that a vapor can travel out to either the cold interface at propulsion engine 106a or the cold interface at propulsion engine 108a.

In addition to being coupled to heat sink 104, heat pipe 108a, heat pipe 108b, heat pipe 108c, and heat pipe 108d are coupled to propulsion engine 106a, propulsion engine 106b, propulsion engine 106c, and propulsion engine 106d, respectively. As depicted, the heat pipes are respectively coupled to a back of the propulsion engines—a place at which a propulsion engine moves air away from the propulsion engine. Put another way, the propulsion engine is configured to generate an airflow that passes over a portion of the heat pipe that is coupled to the propulsion engine. These portions of the heat pipes near the propulsion engines serve as the cold interface of the heat pipes (though, it can be that some vapor also cools and changes state to liquid at points between heat sink 104 and propulsion engines 106a-d).

As depicted, there are four heat pipes and four propulsion engines. It can be appreciated that there can be examples that use more than four heat pipes and four propulsion engines, or that use fewer than four heat pipes and four propulsion engines. Additionally, there can be examples that use a different number of heat pipes and propulsion engines. There can be an example where a UAV comprises three heat pipes and four propulsion engines, or four heat pipes and three propulsion engines (with one propulsion engine serving as a cold interface for multiple heat pipes).

In some examples, heat pipes 108a-d are fused to heat sink 104. In some other examples, a heat sink is omitted, and the heat pipes are directly coupled to the heat source that is to be dissipated. In various examples, this heat source can generally be small cell 102, or some portion of small cell 102, such as a microprocessor of small cell 102, or a power transformer of small cell 102. For example, where a heat pipe is formed into a substantially tubular shape, at the point of the heat source, the heat pipe can be flattened, so that there is an increased surface area of contact between the heat pipe and the heat source relative to a situation where the heat pipe is substantially tubular at the point of the heat source.

Power source 110 is configured to provide electrical power to components of UAV 100 that utilize electrical power, such as small cell 102, and propulsion engines 106a-106d. Each of propulsion engines 106a-106d is configured to generate at least one of lift or directional control for the UAV, and can be implemented as a propeller.

### Heat Sink in a UAV Cooling Mechanism

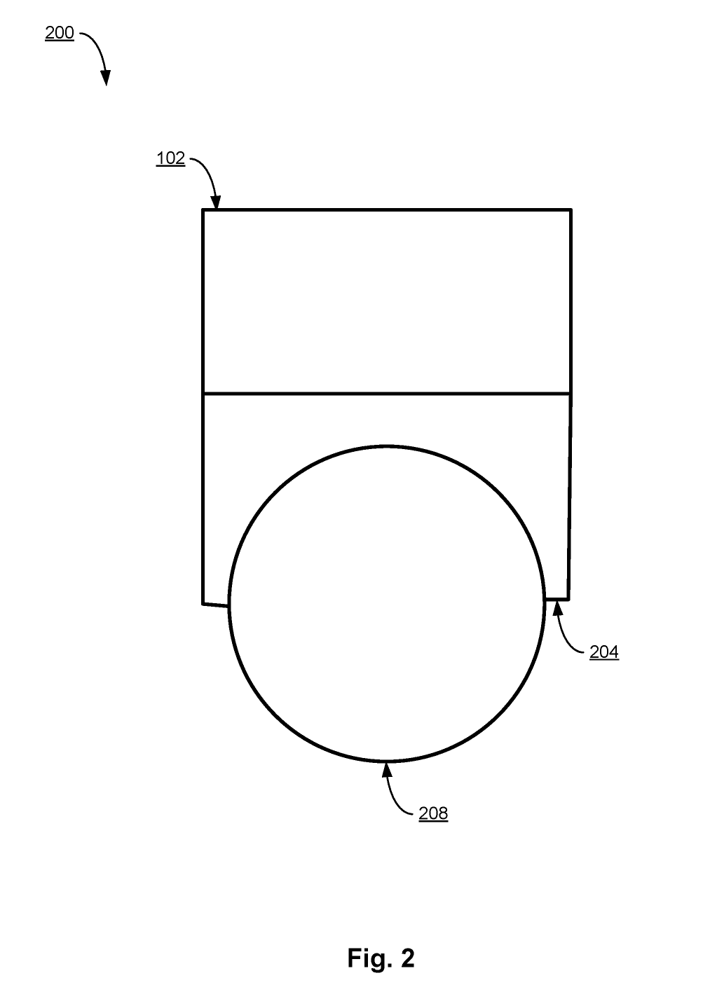

FIG. 2 illustrates an example of a heat sink that connects a portion of a UAV to be cooled with a heat pipe. Cooling system 200 comprises small cell 102, heat sink 204, and heat pipe 208. Similar to as described above, with respect to heat sink 104 of FIG. 1, heat sink 204 is a passive heat exchanger that transfers at least some of the heat generated by small cell 102 away from small cell 102 and dissipates the heat. Small cell 102 can generate heat during the course of the small cell's operation to provide telecommunications services to one or more user devices.

As depicted, heat sink 204 is configured to be in contact with a large portion of both small cell 102, and with heat pipe 208, to aid in heat transfer from small cell 102 to heat pipe 208. Where small cell 102 has a flat surface that is exposed to heat sink 204, heat sink 204 has a flat surface as well, so that small cell 102 and heat sink 204 are in a great deal of contact. Then, where heat pipe 208 has a tubular, rounded surface that is exposed to heat sink 204, then heat sink 204 flares out, so as to maintain contact with the surface of heat pipe 208.

While the example of FIG. 2 depicts one heat pipe, it can be appreciated that there are examples where multiple heat pipes are in contact with a heat sink (such as heat pipes 108a-d of FIG. 1, which are in contact with heat sink 104). In such examples, the heat sink can be configured to maintain a similar amount of contact (such as with the use of multiple flares) with each heat pipe as heat sink 204 has with heat pipe 208.

It can be appreciated that a small cell and a heat pipe can come in other shapes than are depicted here. In such examples, a heat sink between this other small cell and these other heat pipes can be suitably configured to maintain a high amount of contact with each of the small cell and the heat pipes.

### Example Heat Pipe in a UAV Cooling Mechanism

FIG. 3 illustrates an example of a heat pipe for a UAV that includes a heat pipe connected to one propulsion engine. Depicted is cooling mechanism 300. In some examples, four instances of heat pipe 308 can be used to implement heat pipes 108a-d of FIG. 1. Heat pipe 308 has hot interface 314 and cold interface 316. Hot interface 314 is located where heat pipe 308 meets heat sink 104. At hot interface 314, heat pipe 308 absorbs heat from heat sink 104. Liquid 310 within heat pipe 308 is heated in turn, and transforms state to vapor. The vapor travels up and toward propulsion engine 106a and cold interface 316.

As depicted, cold interface 316 is located where heat pipe 308 meets propulsion engine 106a. At cold interface 316, heat pipe 308 dissipates heat. Heat pipe 308 dissipates heat to the air, as air moved by propulsion engine 106a moves air over heat pipe 308. As heat pipe 308 dissipates heat at cold interface 716, vapor 312 is cooled and transforms state into a liquid form. Once in a liquid form, gravity pulls the liquid down, and the liquid travels toward hot interface 314.

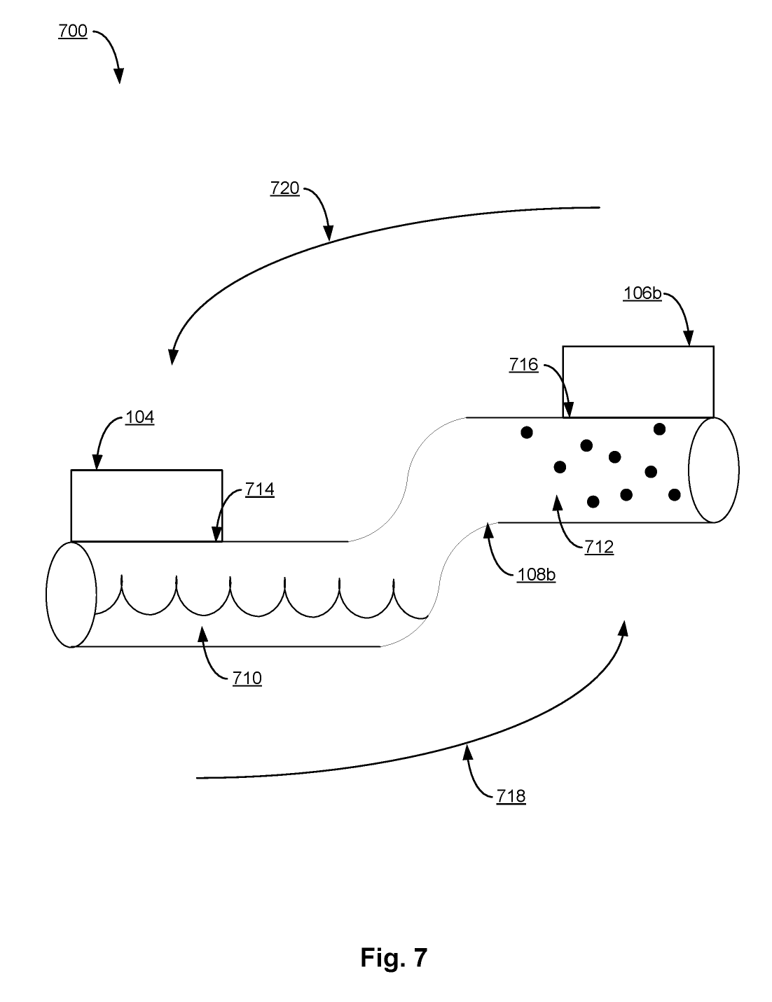

More detail as to how a heat pipe functions to dissipate heat, and the movement of liquid and vapor is described with respect to FIG. 7.

### Another Example Heat Pipe in a UAV Cooling Mechanism

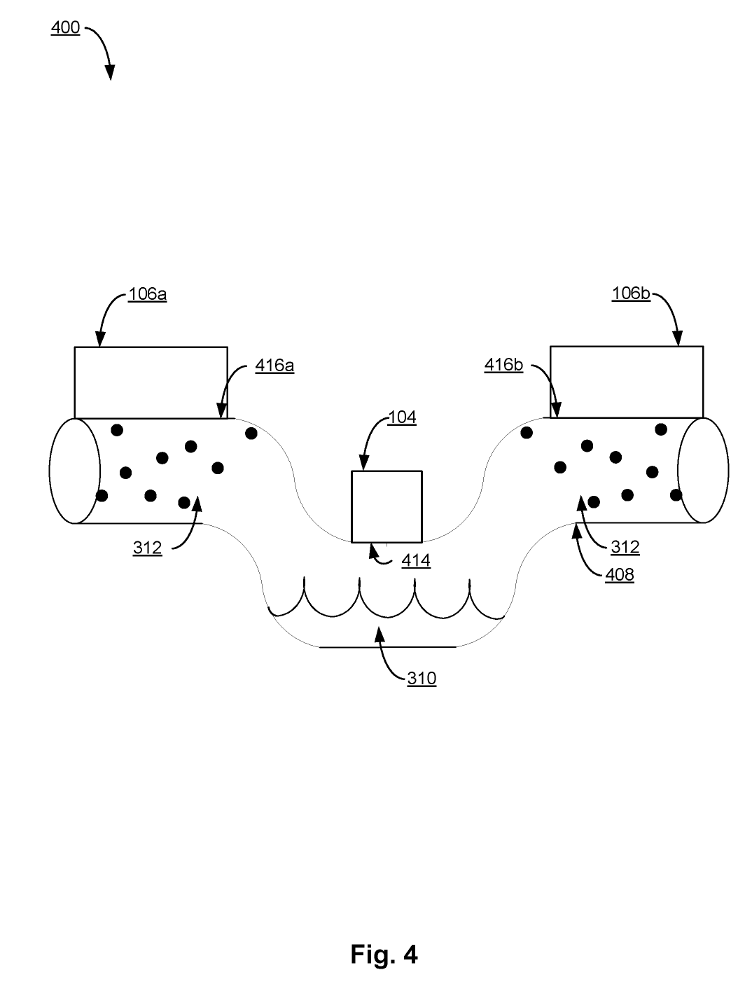

FIG. 4 illustrates a second example of a heat pipe for a UAV that includes a heat pipe connected to two propulsion engines. In some examples, two instances of heat pipe 408 can be used in place of the four heat pipes 108a-d of FIG. 1 to provide a similar level of heat dissipation, as depicted here with cooling mechanism 400. Heat pipe 408 can be considered to be two instances of heat pipe 308 of FIG. 3. Heat pipe 408 is coupled to heat sink 104 at hot interface 414, and is also coupled to two propulsion engines, e.g., propulsion engine 106a and propulsion engine 106b, at cold interface 416a and cold interface 416b, respectively.

As liquid 310 is heated at hot interface 414 and transforms state to vapor, the vapor can travel toward either cold interface 416a or cold interface 416b, as depicted by the presence of vapor 312 at each of these locations within heat pipe 418.

### Another Example Heat Pipe in a UAV Cooling Mechanism

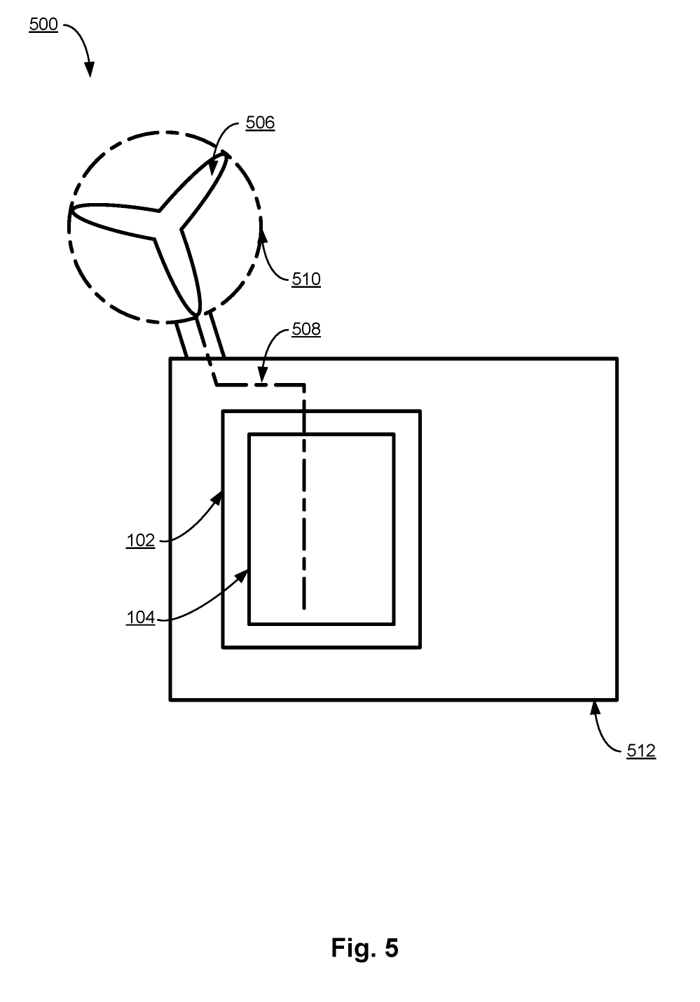

FIG. 5 illustrates a third example of a heat pipe for a UAV that includes the heat pipe serving as a bumper guard for the UAV. FIG. 5 depicts a partial view of UAV 500 for the purpose of emphasizing the features described. UAV 500 comprises UAV body 512, heat sink 104, small cell 102, propulsion engine 506, heat pipe 508, and bumper guard 510.

Here, heat pipe 508 also forms bumper guard 510, i.e., an external shell that protects more sensitive parts of UAV 500 (such as a small cell or power supply) from being hit by an external object during the operation of UAV 500. Bumper guard 510 is depicted as forming a perimeter for propulsion engine 506, so as to decrease a likelihood that an external object of a blade of propulsion engine 506 will come into contact with the blade, which can cause damage to the object or to the blade itself.

UAV Heat Pipe with Fins

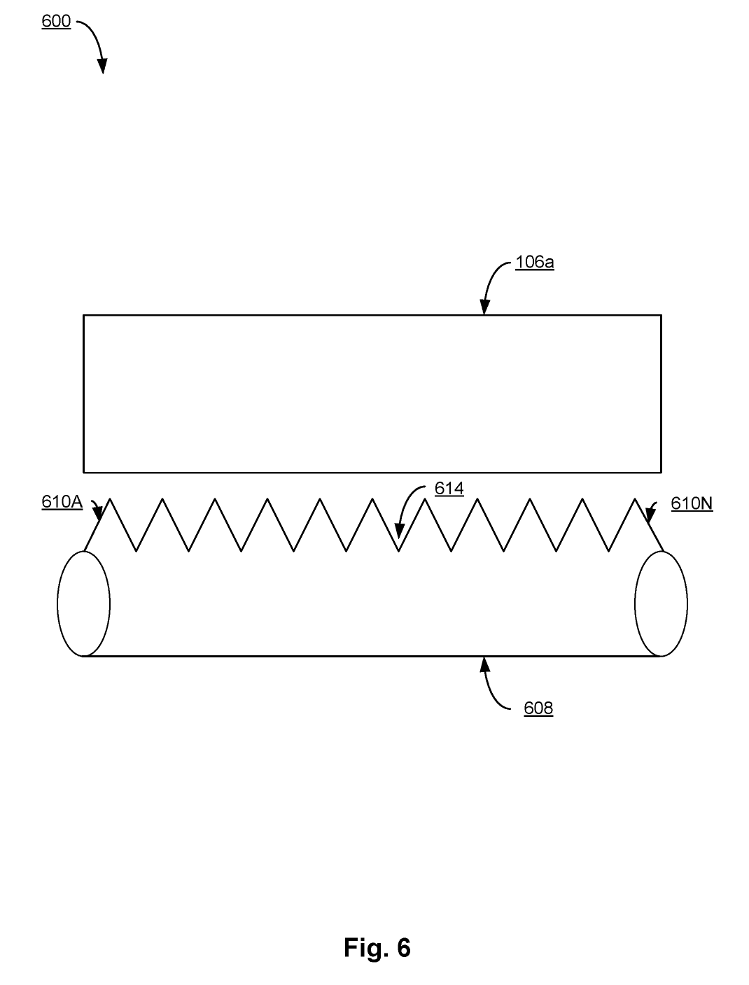

FIG. 6 illustrates an example of fins on a heat pipe for a UAV in cooling mechanism 600. Heat pipe 608 (shown here in a partial view for clarity; heat pipe 608 can also have a hot interface, similar to as shown for heat pipe 308 of FIG. 3, or heat pipe 408 of FIG. 4) comprises a plurality of fins (sometimes referred to as cooling fins), including fin 610a and fin 610n. These fins are located proximal to propulsion engine 106a, at the point of cold interface 614. These fins can increase a surface area of heat pipe 608 so as to increase a size of cold interface 614 of heat pipe 608, which can increase a rate of heat dissipation of heat pipe 608.

It can be appreciated that fins on a heat pipe can be formed into a variety of shapes and configurations, and the example of FIG. 6 is but one example of this variety of shapes and configurations.

Travel of Cooling Fluid within a UAV Heat Pipe

FIG. 7 illustrates an example of how liquid and vapor can flow through a heat pipe to cool a UAV, in cooling mechanism 700. While the example depicted in FIG. 7 is similar to the example depicted in FIG. 3, it can be appreciated that these teachings can be applied to other heat pipes, such as example heat pipe 408 of FIG. 4, example heat pipe 508 of FIG. 5, and example heat pipe 608 of FIG. 6.

Heat pipe 108a has hot interface 714 and cold interface 716. Hot interface 714 is located where heat pipe 108a meets heat sink 104. At hot interface 714, heat pipe 108a absorbs heat from heat sink 104. This absorbed heat is also absorbed by liquid 710 that is contained within heat pipe 108a. Through absorbing heat, liquid 710 transforms state to a vapor form.

Since vapor is generally less dense than a corresponding liquid, as liquid 710 transforms state to a vapor form 718 the vapor travels up heat pipe toward cold interface 716. As depicted, cold interface 716 is located where heat pipe 108a meets propulsion engine 106a. At cold interface 716, heat pipe 108 dissipates heat. Heat pipe 108 dissipates heat to the air, as air moved by propulsion engine 106a moves air over heat pipe 108. As heat pipe 108 dissipates heat at cold interface 716, vapor 712 is cooled and transforms state into a liquid form. Once in a liquid form, gravity pulls the liquid down 720, and the liquid travels toward hot interface 714.

Through the use of gravity to transport liquid 710 and vapor 712, heat pipe 108a provides for heat dissipation without directly consuming more power (though, with heat pipe 108a having a mass, more power can be involved in keeping the UAV that holds heat pipe 108a aloft). Additionally, air flow at cold interface 716 that aids in dissipating heat from heat pipe 108a is preexisting air flow generated by propulsion engine 106a, rather than additional air flow that power is consumed in generating. In this sense, heat pipe 108a provides passive cooling to a UAV that comprises small cell 102.

Forming a UAV with a Heat Pipe

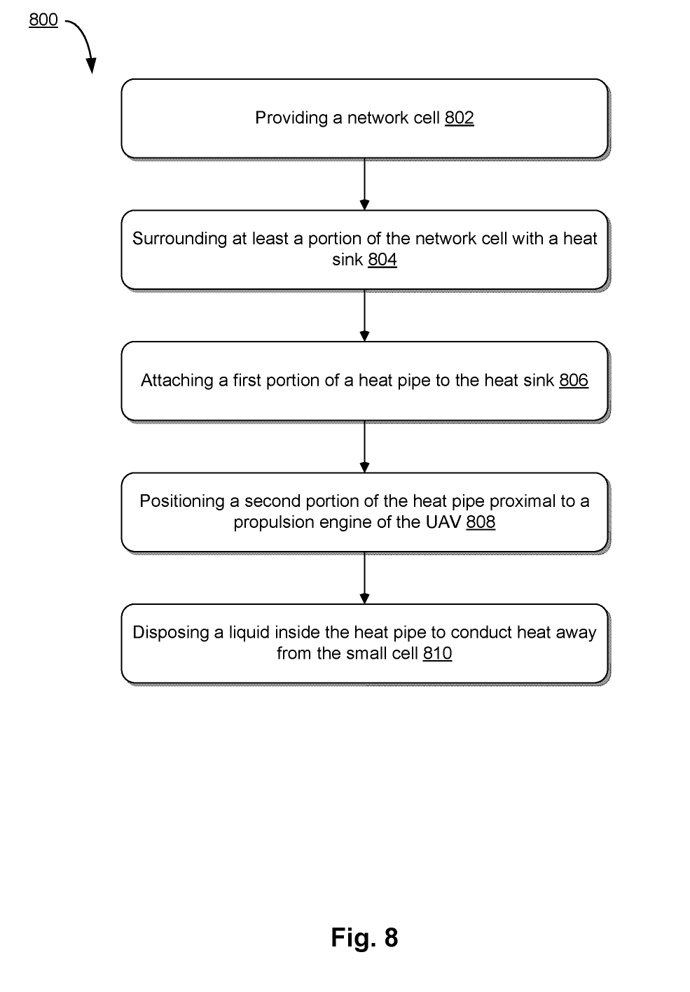

FIG. 8 illustrates a flow diagram of example operating procedures 800 for forming a UAV that includes a heat pipe. In some examples, operating procedures 800 can be implemented to construct UAV 100 of FIG. 1. It can be appreciated that operating procedures 800 of FIG. 8 are example operating procedures, and that there can be examples that implement more or fewer operations than are depicted, or that implement the operations in a different order than is depicted here.

Operating procedures 800 begin with operation 802, which depicts providing a network cell. In some examples, this network cell can be a small cell, and/or can generate heat during operation. In some examples the network cell of operation 802 can be small cell 102 of FIG. 1. This network cell can operate to wirelessly communicate with one or more user devices as part of a telecommunications network.

While the network cell operates to wirelessly communicate with one or more user devices, the network cell can generate heat. For example, a power transformer, power supply, microprocessor, or antenna of the network call can generate heat during the network cell's operation. After operation 802, the operating procedures of FIG. 8 move to operation 804.

Operation 804 depicts surrounding at least a portion of the network cell with a heat sink. As applied UAV 100 of FIG. 1, the network cell can be small cell 102, and the heat sink can be heat sink 104. A portion of the network cell can be surrounded by the heat sink by placing one or more surfaces of the heat sink in contact with one or more surfaces of the network cell, so as to facilitate heat transfer from the network cell to the heat sink.

Additionally, in some examples, thermal grease can be deposited between at least a portion of the heat sink and at least a portion of the network cell. A thermal grease can comprise a polymerizable liquid matrix, and an electrically insulating and thermally-conductive filler material. Examples of a polymerizable liquid matrix include materials such as epoxies, silicones, urethanes, and acrylates. Examples of an electrically insulating and thermally-conductive filler material include aluminum oxide, boron nitride, zinc oxide, and aluminum nitride.

Thermal grease can be deposited between at least a portion of the heat sink and at least a portion of the network cell to aid heat transfer to the heat sink and from the network cell. The thermal grease can operate to aid heat transfer to the heat sink and from the network cell by reducing a presence of an air gap or space between the heat sink and the network cell, where an air gap or space can function as a thermal insulator. After operation 804, the operating procedures of FIG. 8 move to operation 806.

Operation 806 depicts attaching a first portion of a heat pipe to a heat sink. In some examples, a first portion of a heat pipe can be attached to a heat sink similar to as depicted with respect to heat pipe 208 and heat sink 204 of FIG. 2. After operation 806, the operating procedures of FIG. 8 move to operation 808.

Operation 808 depicts positioning a second portion of the heat pipe proximal to a propulsion engine of a UAV. In some examples, a second portion of the heat pipe can be attached to a propulsion engine of a UAV that generates air flow during operation in a similar manner as depicted with respect to heat pipe 108a and propulsion engine 106a of FIG. 1. In other examples, a second portion of the heat pipe can be attached to a propulsion engine of a UAV that generates air flow during operation in a similar manner as depicted with respect to heat pipe 508 and propulsion engine 506 of FIG. 5.

In some examples, the second portion of the heat pipe is coupled to a portion of the propulsion engine, such as being bolted or otherwise fastened to an outer casing of the propulsion engine. In other examples, the second portion of the heat pipe is positioned so that air flow generated by the propulsion engine when the propulsion engine is operating flows over the heat pipe, though the second portion of the heat pipe may not be directly coupled to the propulsion engine.

For instance, the heat pipe can be formed from a substantially rigid material and shaped so that the second portion of the heat pipe is located proximal to a back side of the propulsion engine. Thus, even though the second portion of the heat pipe may not be directly coupled to the heat pipe, the second portion of the heat pipe can still maintain a position such air flow from the propulsion engine when the propulsion engine is operating flows over the second portion of the heat pipe.

In some examples, the propulsion engine generates air flow during operation. After operation 808, the operating procedures of FIG. 8 move to operation 810.

Operation 810 depicts disposing a liquid inside the heat pipe to conduct heat away from the network cell. In some examples, the liquid can be deposited inside the heat pipe and then the heat pipe can be sealed, such as by fusing or welding shut an opening in the heat pipe through which the liquid is deposited.

In some examples, the liquid can be selected to have a boiling point below a temperature to which the liquid will be heated by the network cell. For example, water, with a boiling point of 100C at sea level, might be used as the liquid where the network cell will heat a portion of the heat pipe to a temperature above 100C, causing the water to change state from a liquid to a vapor. Likewise, the liquid can be selected such that it has a freezing point above a temperature to which the heat pipe is subjected during operation.

In other examples, other liquids can be selected for depositing in the heat pipe based on a range of temperatures that the heat pipe can experience during operation of the heat pipe. After operation 810, the operating procedures of FIG. 8 end.

Operating a UAV with a Heat Pipe

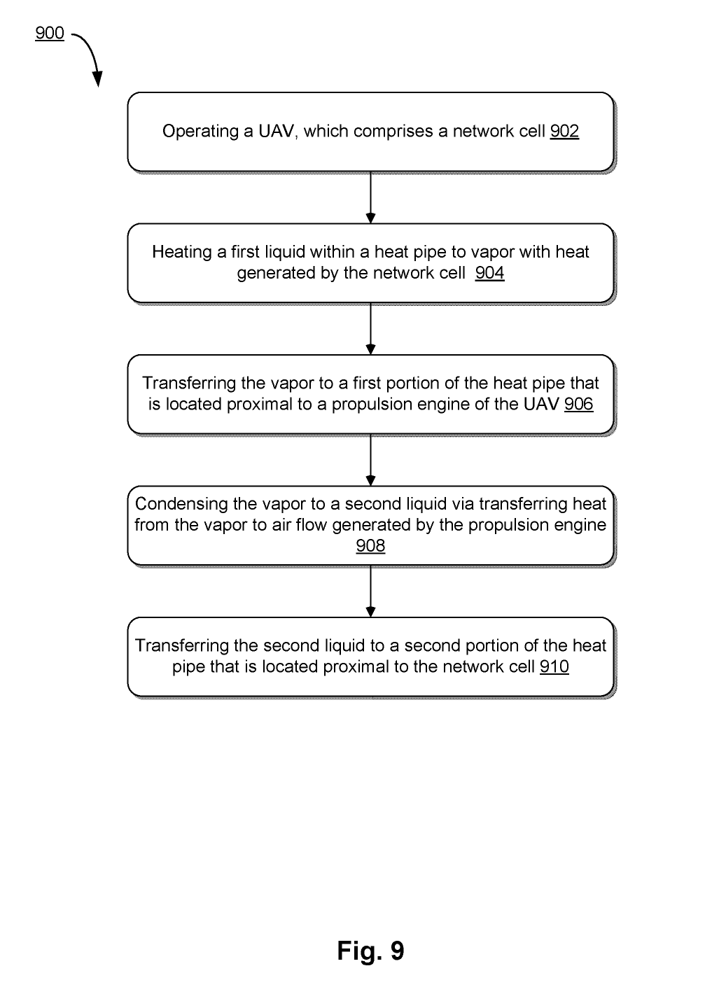

FIG. 9 illustrates a flow diagram of example operating procedures 900 for using a heat pipe to cool a UAV. In some examples, operating procedures 900 can be implemented to cool UAV 100 of FIG. 1 during the operation of UAV 100 as small cell 102 provides telecommunications network services to one or more user devices. It can be appreciated that operating procedures 900 of FIG. 9 are example operating procedures, and that there can be examples that implement more or fewer operations than are depicted, or that implement the operations in a different order than is depicted here.

Operating procedures 900 begin with operation 902, which depicts operating a UAV that comprises a network cell. In some examples, this network cell can comprise a small cell. In some examples, operating a UAV that comprises a network cell can comprise flying a UAV above a geographical area that is to have telecommunications network connectivity. Then, the UAV's network cell can provide that telecommunications network connectivity by conducting wireless communications with one or more user devices in the geographical area, as well as other parts of a telecommunications network. After operation 902, the operating procedures of FIG. 9 move to operation 904.

Operation 904 depicts heating a first liquid within a heat pipe to a vapor with heat generated by the network cell. As the network cell operates in operation 902, the network cell can generate heat that is to be dissipated via the heat pipe. This portion of the heat pipe where the first liquid is heated to a vapor with heat generated by the network cell is sometimes referred to as a hot interface of the heat pipe.

The heat pipe operates to absorb at least some of the heat generated by the network cell. As the heat pipe absorbs at least some of the heat generated by the network cell, a first liquid within the heat pipe is heated. As the first liquid is heated past its boiling point (e.g., 100 C for water at sea level), the first liquid changes state from a liquid to a vapor. After operation 904, the operating procedures of FIG. 9 move to operation 906.

Operation 906 depicts transferring the vapor to a first portion of the heat pipe that is located proximal to a propulsion engine of the UAV. In some examples, the heat pipe can be shaped into a form so that vapor travels from a point where the first liquid changes state from a liquid to a vapor to a first portion of the heat pipe that is located proximal to a propulsion engine of the UAV.

For example, the heat pipe can be constructed into a form so that, when used, the point where the first liquid changes state from a liquid to a vapor is located lower than the first portion of the heat pipe that is located proximal to a propulsion engine of the UAV. Since vapor generally rises relative to water, the vapor can then travel to this higher point, and can be transferred to the first portion of the heat pipe that is located proximal to a propulsion engine of the UAV. After operation 906, the operating procedures of FIG. 9 move to operation 908.

Operation 908 depicts condensing the vapor to a second liquid via transferring heat from the vapor to an air flow generated by the propulsion engine. The air flow generated by the propulsion engine can pass over a portion of the heat pipe, causing heat to transfer from the heat pipe (and the vapor contained within the heat pipe) to this air flow. By transferring heat from the vapor and out of the heat pipe, a temperature of the vapor can drop below the vapor's boiling point, and the vapor can change state from vapor to the second liquid.

It can be appreciated that the first liquid and the second liquid both can contain substantially the same molecules, though at different points in time. Here, the first liquid denotes a time before this liquid changes state from liquid to vapor, and the second liquid denotes a time after this liquid changes state from vapor back to liquid.

This portion of the heat pipe where the vapor is cooled to a second liquid with heat dissipated by the heat pipe is sometimes referred to as a cold interface of the heat pipe. After operation 908, the operating procedures of FIG. 9 move to operation 910.

Operation 910 depicts transferring the second liquid to a second portion of the heat pipe that is located proximal to the network cell. As described above, with respect to operation 906, the heat pipe can be configured so that it is not level during operation—that one point of the heat pipe is situated higher than another point of the heat pipe, so that gravity can act upon a liquid or vapor within the heat pipe to move that liquid or vapor. That is, a cold interface of the heat pipe can be located above a hot interface of the heat pipe during operation of the heat pipe.

Thus, given that a liquid is generally denser than its corresponding vapor, when the vapor changes state to the second liquid, gravity can cause the second liquid to travel from where the second liquid was generated (at a portion of the heat pipe proximal to an air flow generated by the propulsion engine) to a second portion of the heat pipe that is located proximal to the network cell. After operation 910, the operating procedures of FIG. 9 end.

In some examples, the operating procedures of FIG. 9 can be reheated to continue to cool the network cell. For example, when the second liquid returns to a hot interface of the heat pipe, it can be re-heated past its boiling point by absorbing heat generated by the network cell. The vapor generated by this re-heating can then travel to a cold interface of the heat pipe, where the vapor's heat is dissipated. The vapor can then change state back to a liquid and return to the hot interface of the heat pipe. This cycle of heating a liquid to vapor at a hot interface of the heat pipe, transferring the vapor to a cold interface of the heat pipe, cooling the vapor to liquid, and transferring the resulting liquid to the hot interface of the heat pipe can repeat during operation of the UAV to cool the UAV's network cell.

What is claimed is:

1. An unmanned aerial vehicle (UAV), comprising:
a propulsion engine configured to generate at least one of lift or directional control for the UAV;
a network cell; and
a heat pipe, wherein a first portion of the heat pipe is coupled to the network cell, and wherein a second portion of the heat pipe is located proximal to the propulsion engine.

2. The UAV of claim 1, wherein the network cell and the first portion of the heat pipe are coupled via a heat sink, and wherein the heat sink is configured to draw heat from the network cell.

3. The UAV of claim 1, wherein the network cell and the first portion of the heat pipe are coupled via a heat sink, and wherein the heat pipe is configured to draw heat from the heat sink.

4. The UAV of claim 1, wherein the second portion of the heat pipe that is located proximal to the propulsion engine comprises a cooling fin.

5. The UAV of claim 1, wherein the second portion of the heat pipe is configured in a substantially circular shape.

6. The UAV of claim 1, wherein the heat pipe contains a liquid.

7. The UAV of claim 1, wherein the second portion of the heat pipe is located at a back of the propulsion engine.

8. The UAV of claim 1, wherein the heat pipe is configured to convert a state of a substance within the heat pipe from a liquid state to a gaseous state at a point proximal to the heat sink.

9. The UAV of claim 1, wherein the heat pipe is configured to convert a state of a substance within the heat pipe from a gaseous state to a liquid state at a point proximal to the propulsion engine.

10. The UAV of claim 1, wherein the first portion of the heat pipe is coupled to the network cell via a heat sink.

11. The UAV of claim 1, wherein a portion of the heat pipe that is coupled to the propulsion engine comprises a bumper guard of the UAV.

12. The UAV of claim 1, further comprising a second propulsion engine, and wherein the heat pipe is coupled to the second propulsion engine.

13. A method of forming an unmanned aerial vehicle (UAV), comprising:
providing a network cell;
surrounding at least a portion of the network cell with a heat sink;
attaching a first portion of a heat pipe to the heat sink;
positioning a second portion of the heat pipe proximal to a propulsion engine of the UAV; and
disposing a liquid inside the heat pipe to conduct heat away from the network cell.

14. The method of claim 13, wherein the network cell generates heat during operation.

15. The method of claim 13, further comprising:
disposing a thermal grease between at least a portion of the network cell and at least a portion of the heat sink.

16. The method of claim 13, wherein the propulsion engine of the UAV generates air flow during operation.

17. A method for cooling an unmanned aerial vehicle (UAV), comprising:
operating the UAV, which comprises a network cell;
heating a first liquid within a heat pipe to a vapor with heat generated by the network cell;
transferring the vapor to a first portion of the heat pipe that is located proximal to a propulsion engine of the UAV; and
condensing the vapor to a second liquid via transferring heat from the vapor to an air flow generated by the propulsion engine.

18. The method of claim 17, further comprising:
transferring the second liquid to a second portion of the heat pipe that is located proximal to the network cell.

19. The method of claim 17, wherein the network cell generates heat via wirelessly communicating with a user device.

20. The method of claim 17, wherein the propulsion engine is configured to generate at least one of lift or directional control for the UAV.
